(19) United States
(12) Patent Application Publication
(10) Pub. No.: US 2009/0166669 A1
(43) Pub. Date: Jul. 2, 2009

(54) NITRIDE SEMICONDUCTOR LIGHT EMITTING DEVICE AND METHOD OF MANUFACTURING THE SAME

(75) Inventors: Je Won Kim, Seoul (KR); Yong Chun Kim, Seongnam (KR); Sang Won Kang, Suwon (KR); Seok Min Hwang, Busan (KR); Seung Wan Chae, Yongin (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/251,782

(22) Filed: Oct. 15, 2008

(30) Foreign Application Priority Data
Dec. 27, 2007 (KR) 10-2007-0139161

(51) Int. Cl. H01L 21/20; H01L 33/00

(52) U.S. Cl. 257/103; 438/46; 257/E33.023; 257/E21.09

(57) ABSTRACT

A nitride semiconductor light emitting device and a method of manufacturing the same, which can prevent crystal defects such as dislocation while ensuring uniform current spreading into an active layer. The nitride semiconductor light emitting device includes a first n-nitride semiconductor layer formed on a substrate, a first intermediate pattern layer formed on the first n-nitride semiconductor layer, the first intermediate pattern layer having a nanoscale dot structure made of Si compound, a second n-nitride semiconductor layer formed on the first n-nitride semiconductor layer, a second intermediate pattern layer formed on the second n-nitride semiconductor layer, the second intermediate pattern layer having a nanoscale dot structure made of Si compound, which is electrically insulating, a third n-nitride semiconductor layer formed on the second n-nitride semiconductor layer, an active layer formed on the third n-nitride semiconductor layer, and a p-nitride semiconductor layer formed on the active layer.

### CROSS-REFERENCE TO RELATED APPLICATIONS

This application claims the priority of Korean Patent Application No. 2007-139161, filed on Dec. 27, 2007, in the Korean Intellectual Property Office, the disclosure of which is incorporated herein by reference.

### BACKGROUND OF THE INVENTION

1. Field of the Invention

The present invention relates to a nitride semiconductor light emitting device and a method of manufacturing the same, in particular, which can prevent crystal defects such as dislocation and ensure uniform current spreading into an active layer.

2. Description of the Related Art

Conventional nitride semiconductor light emitting devices may include, for example, GaN semiconductor light emitting devices. The GaN semiconductor light emitting devices are applied to blue/green Light Emitting Diode (LED) devices and high switching and high power devices, such as Metal Epitaxial Semiconductor Field Effect Transistor (MESFET) and High Electron Mobility Transistor (HEMT). In particular, blue/green LED devices are mass-produced, and the worldwide circulation thereof is exponentially increasing.

In the field of light emitting devices, such as Light Emitting Diode (LED) and Laser Diode (LD), of industrial fields to which GaN semiconductor is applied, semiconductor light emitting devices, which emit blue light, are receiving attention. In the crystal layer of the blue light emitting device, group II dopant such as Mg or Zn occupies Ga position of GaN semiconductor.

As an example of the conventional GaN semiconductor light emitting device, a light emitting device having a Multiple Quantum Well (MQW) structure is shown in FIG. 1. The light emitting device is formed on a substrate 1, generally, made of sapphire or SiC. The light emitting device includes a buffer layer 2 made of an Al_{y}Ga_{1-y}N polycrystalline film, grown on the SiC substrate 1, and a GaN underlayer 3 formed on the buffer layer 2 at high temperature. The light emitting device also includes, sequentially on the GaN underlayer 3, a light-generating active layer 4, an AlGaN electron barrier layer 5, a Mg-doped InGaN layer 6 and a Mg-doped GaN layer 7. The AlGaN electron barrier layer 5, the Mg-doped InGaN layer 6 and the Mg-doped GaN layer 7 are doped with Mg, and are converted into p type by thermal annealing.

An insulating layer is formed on the Mg-doped GaN layer 7 and the GaN under layer 3, and a P-electrode 9 and an N-electrode 10, matching each other, are formed, thereby realizing the light emitting device.

In this type of nitride semiconductor light emitting device, electrons and holes are injected into the active layer 4, so that light is generated by the recombination of the electrons and the holes. In order to improve the luminous efficiency of the active layer 4, studies have been actively carried out in two aspects, such as internal quantum efficiency and external quantum efficiency (e.g., light extraction efficiency). In general, the improvement related with internal quantum efficiency aims to fundamentally raise the light efficiency of the active layer 4, and is focused on the crystal quality of the active layer 4.

On the other aspect, internal quantum efficiency is greatly degraded by non-uniform current spreading. That is, a partial area A of the active layer 4 has a high current density, but the other areas of the active layer 4 have a relatively lower current density, so that the whole areas of the active layer 4 do not act as light emitting area, thereby degrading internal quantum efficiency.

An approach to improve external quantum efficiency or light extraction efficiency is to adjust the reflectivity and the surface flatness of nitride semiconductor material. However, since the reflectivity of the nitride semiconductor material can be changed in a small range, external quantum efficiency can be improved little. In the case of adjusting surface flatness, the surface of a device is made coarse to reduce total internal reflection angle, thereby reducing light loss inside the device. However, it is required to additionally form patterns, via Metal-Organic Chemical Vapor Deposition (MOCVD) or other Chemical Vapor Deposition (CVD) processes, in order to achieve surface coarseness.

Although various approaches have been sought to improve the luminous efficiency of nitride semiconductor light emitting devices as mentioned above, there are still demands in the art for new and more effective measures, which can enhance luminous efficiency by improving electrical and optical properties.

### SUMMARY OF THE INVENTION

The present invention has been made to solve the foregoing problems with the prior art, and therefore the present invention is directed to a nitride semiconductor light emitting device, which can ensure uniform current spreading into an active layer in order to improve luminous efficiency.

The present invention is also directed to a method of manufacturing a nitride semiconductor light emitting device, which can ensure uniform current spreading into an active layer in order to improve luminous efficiency.

According to an aspect of the present invention, the nitride semiconductor light emitting device includes a substrate; a first n-nitride semiconductor layer formed on the substrate; a first intermediate pattern layer formed on the first n-nitride semiconductor layer, the first intermediate pattern layer having a nanoscale dot structure made of Si compound; a second n-nitride semiconductor layer formed on the first n-nitride semiconductor layer, on which the first intermediate pattern layer is formed; a second intermediate pattern layer formed on the second n-nitride semiconductor layer, the second intermediate pattern layer having a nanoscale dot structure made of Si compound, which is electrically insulating; a third n-nitride semiconductor layer formed on the second n-nitride semiconductor layer, on which the second intermediate pattern layer is formed; an active layer formed on the third n-nitride semiconductor layer; and a p-nitride semiconductor layer formed on the active layer.

The nitride semiconductor light emitting device may have a mesa-etched structure, which is etched from part of the p-nitride semiconductor layer to expose part of the second n-nitride semiconductor layer, and may further include an n-electrode formed on the exposed area of the second n-nitride semiconductor layer; and a p-electrode formed on the p-nitride semiconductor layer.

Each of the first and second intermediate pattern layer may be made of one selected from a group consisting of SiO₂, SiN and SiC.

The first and second intermediate pattern layer may be made of same Si compound.

The first intermediate pattern layer may have a thickness ranging from 1 nm to 10 nm, and the second intermediate pattern layer may have a thickness ranging from 1 nm to 10 nm.

According to another aspect of the present invention, the method of manufacturing a nitride semiconductor light emitting device includes: forming a first n-nitride semiconductor layer on a prepared substrate; forming a first intermediate pattern layer on the first n-nitride semiconductor layer, the first intermediate pattern layer having a nanoscale dot structure made of Si compound; forming a second n-nitride semiconductor layer on the first n-nitride semiconductor layer, on which the first intermediate pattern layer is formed; forming a second intermediate pattern layer on the second n-nitride semiconductor layer, the second intermediate pattern layer having a nanoscale dot structure made of Si compound, which is electrically insulating; and forming a third n-nitride semiconductor layer on the second n-nitride semiconductor layer, on which the second intermediate pattern layer is formed.

The substrate may be made of one selected from a group consisting of Al₂O₃, SiC, ZnO, Si, GaAs, GaP, LiAl₂O₃, BN, AIN and GaN, or be a template substrate having a material layer, which is made of one selected from a group consisting of GaN, InGaN, AlGaN and AlGaInN.

The step of forming a first intermediate pattern layer may be carried out in situ between the forming of a first n-nitride semiconductor layer and the forming of a second n-nitride semiconductor layer.

The step of forming a second intermediate pattern layer may be carried out in situ between the forming of a second n-nitride semiconductor layer and the forming of a third n-nitride semiconductor layer.

The Si compound may be one selected from a group consisting of SiO₂, SiN and SiC.

The first and second intermediate pattern layer may be made of same Si compound.

The first intermediate pattern layer may have a thickness ranging from 1 nm to 10 nm, and the second intermediate pattern layer may have a thickness ranging from 1 nm to 10 nm.

According to the nitride semiconductor light emitting device of the present invention as set forth above, the first and second intermediate pattern layers, which have a nanoscale dot structure made of Si compound, are provided inside the n-nitride semiconductor layer in order to prevent defects such as dislocation and ensure uniform current spreading into the active layer, thereby electrically and optically enhancing luminous efficiency.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view illustrating an example of a conventional nitride semiconductor light emitting device;

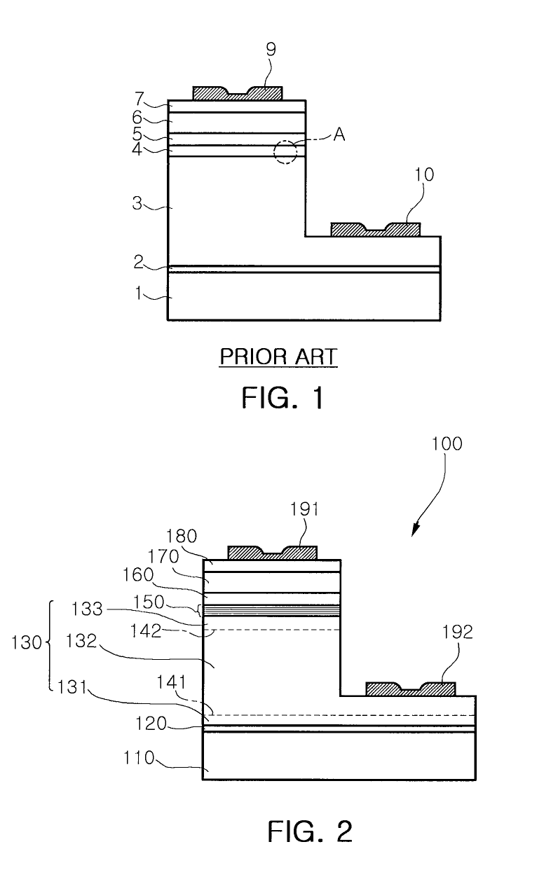

FIG. 2 is a cross-sectional view illustrating a nitride semiconductor light emitting device according to an embodiment of the present invention;

FIG. 3 is a cross-sectional view illustrating a nitride semiconductor light emitting device according to another embodiment of the present invention; and

FIGS. 4A to 4D are cross-sectional views illustrating a method of manufacturing the nitride semiconductor light emitting device as shown in FIG. 2.

### DETAILED DESCRIPTION OF THE EXEMPLARY EMBODIMENTS

The present invention will now be described more fully with reference to the accompanying drawings, in which exemplary embodiments thereof are shown.

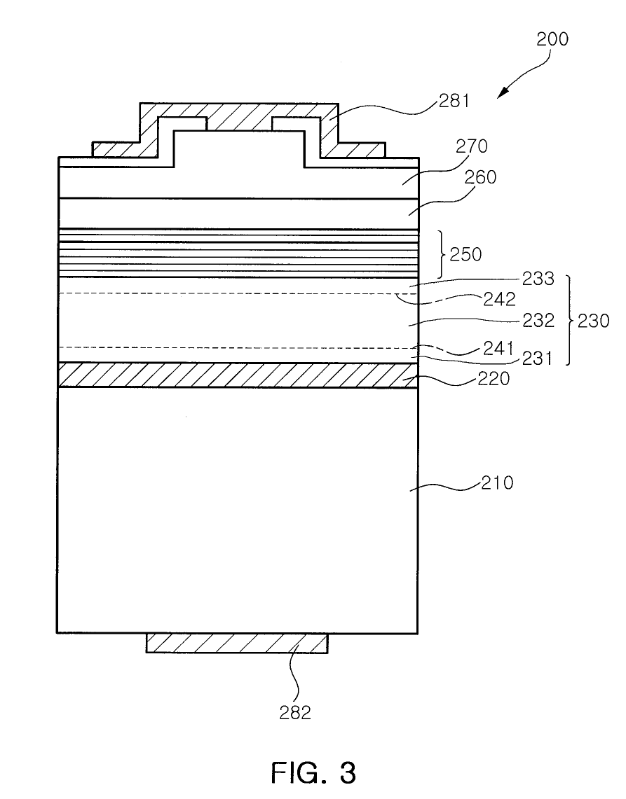

FIG. 2 is a cross-sectional view illustrating a nitride semiconductor light emitting device 100 according to an embodiment of the present invention. The nitride semiconductor light emitting device 100 according to this embodiment will be described by way of example as being a horizontal type.

As shown in FIG. 2, the nitride semiconductor light emitting device 100 includes an n-nitride semiconductor layer 130 formed on a substrate 110, with an n-electrode 192 mounted on an exposed area of the n-nitride semiconductor layer 130. The n-nitride semiconductor layer 130 has at least two intermediate pattern layers 141 and 142 therein. The nitride semiconductor light emitting device 100 also includes, sequentially on the n-nitride semiconductor layer 130, an MQW active layer 150 including quantum well layers and quantum barrier layers alternating with each other, an electron barrier layer 160 made of p-nitride including Al, an p-nitride semiconductor layer 170 made of p-nitride for hole injection and a transparent electrode layer 180 with a p-electrode 191 formed on the top surface thereof.

Of course, a buffer layer 120 made of, for example, AlN/GaN can be interposed between the substrate 110 and the n-nitride semiconductor layer 130 in order to solve the lattice mismatch therebetween.

The substrate 110 is a typical type of substrate, which is used for manufacturing a nitride semiconductor light emitting device. For example, the substrate 110 may be a substrate, which is made of, for example, Al₂O₃, SiC, ZnO, Si, GaAs, GaP, LiAl₂O₃, BN, AIN or GaN, and is treated by lapping and polishing to have a transparent and plane surface, or a template substrate, which has a GaN-based material layer made of, for example, GaN, InGaN, AlGaN and AlGaInN.

The n-nitride semiconductor layer 130 includes a first n-nitride semiconductor layer 131, a second n-nitride semiconductor layer 132 and a third n-nitride semiconductor layer 133, sequentially formed on the substrate 110. The two intermediate pattern layers 141 and 142 are formed inside the n-nitride semiconductor layer 130. That is, the first intermediate pattern layer 141 is formed between the first n-nitride semiconductor layer 131 and the second n-nitride semiconductor layer 132, which are sequentially formed on the substrate 110, and the second intermediate pattern layer 142 is formed between the second n-nitride semiconductor layer 132 and the third n-nitride semiconductor layer 133. Here, the n-electrode 192 is formed on an exposed area of the second n-nitride semiconductor layer 132 of the n-nitride semiconductor layer 130.

Specifically, the first intermediate pattern layer 141 and the second intermediate pattern layer 142 inside the n-nitride semiconductor layer 130 are formed with a thickness of 1 nm to 10 nm, in positions adjacent to the substrate 110 and the active layer 150, respectively. Each of the intermediate pattern layers 141 and 142 has at least one layer structure, which includes a plurality of dots made of Si compound such as SiO₂, SiN or SiC. The first intermediate pattern layer 141 is formed to enhance the lateral growth of the n-nitride semiconductor layer 130, including the second n-nitride semiconductor layer 132, and prevent crystal defects such as dislocation. The second intermediate layer 142 is formed to micro-locally stop the flow of current across the entire area, thereby ensuring uniform current spreading into the active layer 150.

The active layer 150 has an MQW structure including quantum well layers and quantum barrier layers alternating with each other. The quantum barrier layers are made of Al_{X1}In_{Y}Ga_{(1-X1-Y)}N, where 0≦X1<1 and 0≦Y<1, and quantum well layers are made of In_{X2}Ga_{1-X2}N, where 0<x2≦1. Here, a band gap is created, and quantum wells are formed, so that light can be generated through the recombination of electrons and holes.

The electron barrier layer 160 is made of p-nitride containing Al, for example, p-AlGaN, in order to prevent current loss due to the overflowing of electrons. The p-nitride electrode layer 170 is made of p-nitride, such as p-GaN, in order to improve hole injection efficiency. The transparent electrode 180, with the p-electrode 191 on the top surface thereof, can be made of metal oxide, such as ZnO, RuO, NiO, CoO or Indium-Tin-Oxide (ITO).

In the nitride semiconductor light emitting device 100 of this embodiment having the above-described construction, the first and second intermediate pattern layers 141 and 142 are formed inside the n-nitride semiconductor layer 130, thereby preventing defects such as dislocation and ensuring uniform current spreading into the active layer 150. This, as a result, improves electrical and optical properties of the active layer 150, thereby enhancing luminous efficiency.

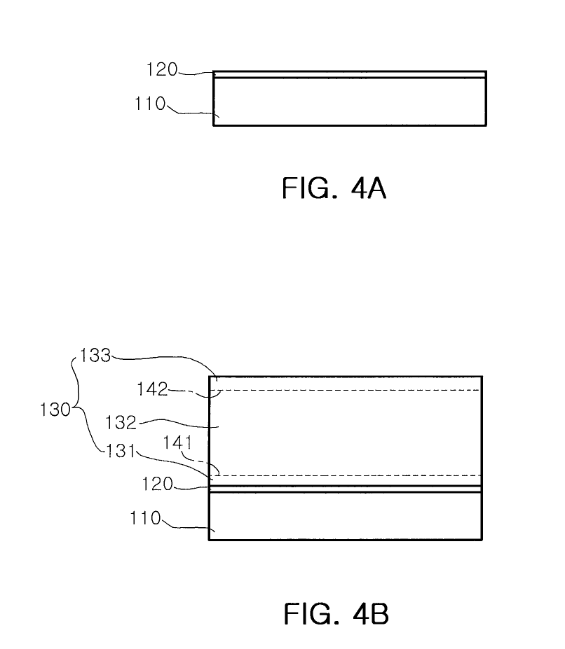

FIG. 3 shows a vertical nitride semiconductor light emitting diode 200 according to another embodiment of the present invention, which has a first intermediate pattern layer 241 and a second intermediate pattern layer 242 inside an n-nitride semiconductor layer 230 in order to prevent defects such as dislocation and ensure uniform current spreading into an active layer 250.

As shown in FIG. 3, the nitride semiconductor light emitting device 200 of this embodiment includes the n-nitride semiconductor layer 230 formed on a substrate 210, with an n-electrode 282 disposed on the bottom of the substrate 210. The n-nitride semiconductor layer 230 has at least two intermediate pattern layers 241 and 242 therein. The nitride semiconductor light emitting device 200 also includes, sequentially on the n-nitride semiconductor layer 230, the active layer 250 having an MQW structure, which includes quantum well layers and quantum barrier layers alternating with each other, an electron barrier layer 260 made of p-nitride including Al, an p-nitride semiconductor layer 270 made of p-nitride for hole injection, with a p-electrode 281 formed on the top surface thereof. Of course, a buffer layer 220 made of, for example, AlN/GaN can be interposed between the substrate 210 and the n-nitride semiconductor layer 230 in order to solve the lattice mismatch therebetween.

In the nitride semiconductor light emitting device 200 of this embodiment, the first intermediate pattern layer 241 between the first n-nitride semiconductor layer 231 and the second n-nitride semiconductor layer 232 can prevent internal defects of the n-nitride semiconductor layer 230, such as dislocation, from moving upwards. The second intermediate pattern layer 242 between the second n-nitride semiconductor layer 232 and the third n-nitride semiconductor layer 233 can ensure uniform current spreading into the active layer 250. This, as a result, improves electrical and optical properties of the active layer 250, thereby enhancing luminous efficiency.

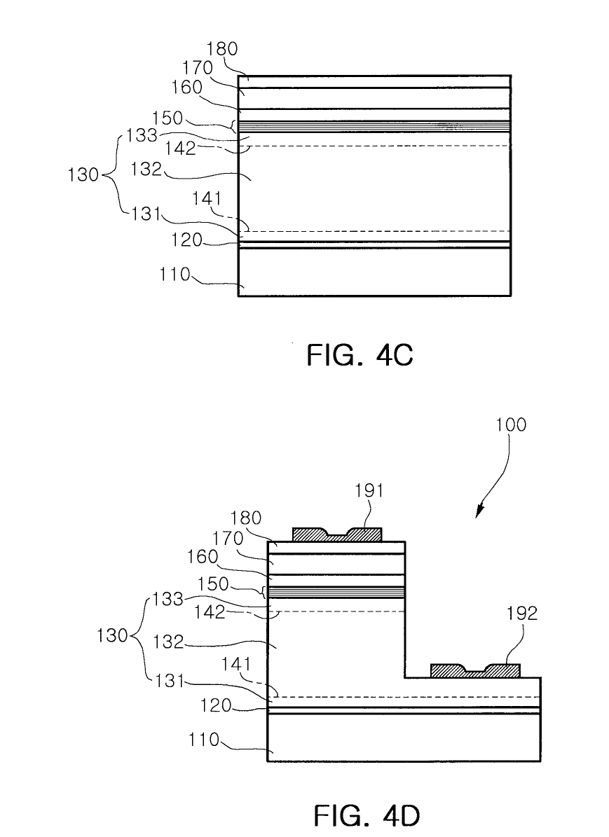

Now, a method of manufacturing a nitride semiconductor light emitting device according to an embodiment of the present invention will be described in detail with reference to FIGS. 4A to 4D. Herein, the nitride semiconductor light emitting device shown in FIGS. 4A to 4D will be described by way of example as being the nitride semiconductor light emitting device 100 shown in FIG. 2. Detailed description of well-known functions and constructions of the nitride semiconductor light emitting device will be omitted when they unnecessarily obscure the present invention.

According to the method of manufacturing the nitride semiconductor light emitting device of the present invention, as shown in FIG. 4A, an AlN/GaN buffer layer 120 is formed on the top surface of a substrate 110. The substrate 110 is a typical type of substrate, which is used for manufacturing a nitride semiconductor light emitting device. For example, the substrate 110 may be a substrate, which is made of, for example, Al₂O₃, SiC, ZnO, Si, GaAs, GaP, LiAl₂O₃, BN, AIN or GaN, and is treated by lapping and polishing to have a transparent and plane surface, or a template substrate, which has a GaN-based material layer made of, for example, GaN, InGaN, AlGaN or AlGaInN.

After the buffer layer 120 is formed on the top surface of the substrate 110, as shown in FIG. 4B, an n-nitride semiconductor layer 130 is formed on the top surface of the buffer layer 120. Here, n-nitride semiconductor layer 130 has first and second intermediate pattern layers 141 and 142 made of Si compound, such as SiO₂, SiN or SiC.

For the growth of the n-nitride semiconductor layer 130, which includes the first n-nitride semiconductor layer 131, the second n-nitride semiconductor layer 132 and the third n-nitride semiconductor layer 133, silane gas containing n-dopant, such as NH₃, Tri-Methyl Gallium (TMG) or Si, is fed, for example, via Metal Organic Chemical Vapor Deposition (MOCVD), Molecular Beam Epitaxy (MBE) or Hydride Vapor Phase Epitaxy (HVPE), thereby to grow the first n-nitride semiconductor layer 131 made of n-GaN on the top surface of the buffer layer 120 to a predetermined thickness, and in situ to the first n-nitride semiconductor layer 131, form the first intermediate pattern layer 141 to a thickness of 1 nm to 10 nm.

For example, in order to form in situ the first intermediate pattern layer 141 from SiN, the supply of TMG is interrupted, and silane gas containing n-dopant, such as NH₃ or Si, is fed, so that a plurality of SiN dots are formed. A plurality of dots, which form the first intermediate pattern layer 141, act as non-surface active substance, thereby spontaneously making nanoscale dots.

Next, the supply of TMG is resumed, and silane gas containing n-dopant, such as NH₃, TMG or Si, is flown again over the first intermediate pattern layer 141, thereby growing the second n-nitride semiconductor layer 132 made of n-GaN to cover the first intermediate pattern layer 141.

After the second n-nitride semiconductor layer 132 covering the first intermediate pattern layer 141 is formed, the supply of TMG is interrupted in the same fashion as in the growth of the first intermediate pattern layer 141, and silane gas containing n-dopant, such as NH₃ or Si, is fed, so that a number of SiN dots can form a layer structure having a thickness of 1 nm to 10 nm as the second intermediate pattern layer 142.

TMG is supplied again to the second intermediate pattern layer 142, and silane gas containing n-dopant, such as NH₃, TMG or Si, is flown over the second pattern layer 142, thereby growing the third n-nitride semiconductor layer 133 made of n-GaN. In the case where the first and second intermediate pattern layers 141 and 142 inside the n-nitride (n-GaN) semiconductor layer 130 is made of SiO₂ instead of SiN, O₂ can be flown instead of NH₃.

After the n-nitride (n-GaN) semiconductor layer 130 including the first and second intermediate pattern layers 141 and 142 therein is formed, as shown in FIG. 4C, an active layer 150, an electron barrier layer 160, a p-nitride semiconductor layer 170 and a transparent electrode layer 180 can be sequentially formed on the top surface of the n-nitride semiconductor layer 130. Here, the active layer 150 includes quantum barrier layers and quantum well layers alternating with each other. The quantum barrier layers are made of Al_{X1}In_{Y}Ga_{(1-X1-Y)}N, where 0≦X1<1 and 0≦Y<1, and the quantum well layers are made of In_{X2}Ga_{1-X2}N, where 0<x2≦1. The electron barrier layer 160 is made of p-nitride containing Al, for example, p-AlGaN. The p-nitride electrode layer 170 is made of p-nitride, such as p-GaN. The transparent electrode 180 is made of metal oxide, such as ZnO, RuO, NiO, CoO or ITO.

After the transparent electrode 180 is formed, as shown in FIG. 4D, etching is performed on the resultant structure, including from the transparent electrode layer 180 through the second intermediate pattern layer 142 of the n-nitride semiconductor layer 130 to the second n-nitride semiconductor layer 132 between the first intermediate pattern layer 141 and the second intermediate pattern layer 142, so that part of the second n-nitride semiconductor layer 132 between the first and second intermediate pattern layers 141 and 142 is exposed. Then, a p-electrode 191 and an n-electrode 192 can be formed on the transparent electrode 180 and the exposed area of the second n-nitride semiconductor layer 132.

According to the present invention, in situ to the manufacturing process of the n-nitride semiconductor layer 130, the first and second intermediate pattern layers 141 and 142 made of Si compound, such as SiO₂, SiN or SiC, are formed inside the n-nitride semiconductor layer 130. The first pattern layer 141 can prevent internal defects of the n-nitride semiconductor layer 130, such as dislocation, from moving, and the second intermediate pattern layer 142 can ensure uniform current spreading into the active layer 150. Accordingly, this makes it possible to produce a nitride semiconductor light emitting device, the luminous efficiency of which is electrically and optically enhanced.

While the present invention has been described with reference to the particular illustrative embodiments and the accompanying drawings, it is not to be limited thereto but will be defined by the appended claims.

It is to be appreciated that those skilled in the art can substitute, change or modify the embodiments in various forms without departing from the scope and spirit of the present invention.

What is claimed is:

1. A nitride semiconductor light emitting device, comprising:
a substrate;
a first n-nitride semiconductor layer formed on the substrate;
a first intermediate pattern layer formed on the first n-nitride semiconductor layer, the first intermediate pattern layer having a nanoscale dot structure made of Si compound;
a second n-nitride semiconductor layer formed on the first n-nitride semiconductor layer, on which the first intermediate pattern layer is formed;
a second intermediate pattern layer formed on the second n-nitride semiconductor layer, the second intermediate pattern layer having a nanoscale dot structure made of Si compound, which is electrically insulating;
a third n-nitride semiconductor layer formed on the second n-nitride semiconductor layer, on which the second intermediate pattern layer is formed;
an active layer formed on the third n-nitride semiconductor layer; and
a p-nitride semiconductor layer formed on the active layer.

2. The nitride semiconductor light emitting device of claim 1, having a mesa-etched structure, which is etched from part of the p-nitride semiconductor layer to expose part of the second n-nitride semiconductor layer,
the device further comprising:
an n-electrode formed on an exposed area of the second n-nitride semiconductor layer; and
a p-electrode formed on the p-nitride semiconductor layer.

3. The nitride semiconductor light emitting device of claim 1, wherein each of the first and second intermediate pattern layer is made of one selected from a group consisting of SiO₂, SiN and SiC.

4. The nitride semiconductor light emitting device of claim 1, wherein the first and second intermediate pattern layer are made of same Si compound.

5. The nitride semiconductor light emitting device of claim 1, wherein the first intermediate pattern layer has a thickness ranging from 1 nm to 10 nm.

6. The nitride semiconductor light emitting device of claim 1, wherein the second intermediate pattern layer has a thickness ranging from 1 nm to 10 nm.

7. A method of manufacturing a nitride semiconductor light emitting device, comprising:
forming a first n-nitride semiconductor layer on a prepared substrate;
forming a first intermediate pattern layer on the first n-nitride semiconductor layer, the first intermediate pattern layer having a nanoscale dot structure made of Si compound;
forming a second n-nitride semiconductor layer on the first n-nitride semiconductor layer, on which the first intermediate pattern layer is formed;
forming a second intermediate pattern layer on the second n-nitride semiconductor layer, the second intermediate pattern layer having a nanoscale dot structure made of Si compound, which is electrically insulating; and
forming a third n-nitride semiconductor layer on the second n-nitride semiconductor layer, on which the second intermediate pattern layer is formed.

8. The method of claim 7, wherein the substrate is made of one selected from a group consisting of Al₂O₃, SiC, ZnO, Si, GaAs, GaP, LiAl₂O₃, BN, AIN and GaN.

9. The method of claim 7, wherein the substrate is a template substrate having a material layer, which is made of one selected from a group consisting of GaN, InGaN, AlGaN and AlGaInN.

10. The method of claim 7, wherein the forming of a first intermediate pattern layer is carried out in situ between the forming of a first n-nitride semiconductor layer and the forming of a second n-nitride semiconductor layer.

11. The method of claim 7, wherein the forming of a second intermediate pattern layer is carried out in situ between the forming of a second n-nitride semiconductor layer and the forming of a third n-nitride semiconductor layer.

12. The method of claim 7, wherein the Si compound is one selected from a group consisting of SiO₂, SiN and SiC.

13. The method of claim 7, wherein the first and second intermediate pattern layer are made of same Si compound.

14. The method of claim 7, wherein the first intermediate pattern layer has a thickness ranging from 1 nm to 10 nm.

15. The method of claim 7, wherein the second intermediate pattern layer has a thickness ranging from 1 nm to 10 nm.
